(19) United States
(12) Patent Application Publication
(10) Pub. No.: US 2003/0155326 A1
(43) Pub. Date: Aug. 21, 2003

(54) Reducing tread separation in tires

(76) Inventor: Nicholas Michael Masich, Woodbury, NJ (US)

Correspondence Address: Nicholas M. Masich, 316 Bowman Dr., Woodbury, NJ, 08096, US

(21) Appl. No.: 10/076,774

(22) Filed: Feb. 15, 2002

(51) Int. Cl. C30B 33/00; B44C 1/22; C03C 15/00; C03C 25/68

(52) U.S. Cl. 216/23

(57) ABSTRACT

This abstract describes two new improvements in present production lines through use of laser-pierced smaller diameter holes in spinnerets through which viscous fluids flow and the addition of continuous wave or pulsed sonic generators at the rear of spinneret housings both of which produce irregularities in the surfaces of the smooth continuous synthetic filaments (nylon and kevlar for examples) to produce yarns and cords with increased cord-to-rubber bonding thus reducing tread separation in tries. The acid etching of steel wire used in tire manufacturing also increases wire-to-rubber bonding with further reductions in tread separation and increased tire life.

### BRIEF SUMMARY OF THE INVENTION

This summary describes two improvements for manufacturing continuous synthetic filaments woven into yarns and cords used in tire manufacturing, and an additional treatment for steel wire strands also used in tire manufacturing. Continuous synthetic filaments are improved through use of laser-pierced smaller diameter holes in spinnerets, through which viscous fluids flow, and the addition of continuous wave or pulsed sonic generators at the back of spinneret housings both of which produce surface irregularities in the smooth synthetic filaments producing cords with stronger cord-to-rubber bonding thus reducing tread separation in tires. Acid etching of steel wire strands used in tire manufacturing also increases steel-to-wire bonding with further reduction in tread separation in tires especially when subjected to higher speeds over bumpy roads.

### DETAILED DESCRIPTION OF INVENTION

This invention describes two improvements in present production lines for manufacturing continuous synthetic filaments (for examples, nylon and kevlar) that are woven into yarns and cords used in tire manufacturing

The first improvement uses spinnerets, through which viscous fluids flow, with smaller diameter holes made by tiny laser-beams replacing presently used spinnerets with larger diameter holes made by mechanical drills. The smaller diameter holes being irregular in shape, similar to those made by a welding torch in steel, form continuous filaments with corresponding surface irregularities resulting in stronger cord-to-rubber bonding thus reducing tread separation and extending tire life.

Installing sonic generators of optimum frequency (continuous or pulsed) of very low amplitude in the rear of spinneret housings produce circumferential ridges and valleys in the spun filaments with further increases in cord-to-rubber bonding and resultant reduced tread separation in tires. These sonic generators can also be added to present production lines to reduce tread separation in tires.

Acid etching of steel wires at the end of current production lines also help reduce tread separation in tires. The wire strands are loosely wound in coils and immersed in an acid bath for an optimal period of time to produce an etched glass appearance. They are next immersed in a caustic solution, then washed and dried. The resulting stronger steel strands-to-rubber bonding further reduces tread separation in tires. This treatment can also be used in present production lines to produce stronger steel strands-to-rubber bonding thus reducing tread separation in tires.

1. What I claim as my invention is substituting laser-pierced smaller diameter holes in spinnerets for presently used larger mechanically drilled holes through which viscous fluids flow to produce continuous synthetic filaments with surface irregularities producing yarns and cords with stronger cord-to-rubber bonding thereby reducing tread separation in tires.

2. What I also claim as my invention is the addition of continuous wave or pulsed sonic generators of optimum frequency and very low amplitudes at the rear of spinneret housings which produce circumferential ridges and valleys in the spun filaments with additional increases in cored-to-rubber bonding thereby reducing tread separation in tires.

3. What I also claim here is the acid etching of steel wires at the end of current production lines to give the appearance of etched glass will also contribute to significant increases in steel-to-rubber bonding thereby reducing tread separation in tires.
